(19) United States
(12) Patent Application Publication
(10) Pub. No.: US 2012/0262660 A1
(43) Pub. Date: Oct. 18, 2012

(54) DISPLAY DEVICE

(75) Inventors: Masaki Fujiwara, Osaka (JP); Yasumori Fukushima, Osaka (JP)

(73) Assignee: Sharp Kabushiki Kaisha, Osaka (JP)

(21) Appl. No.: 13/518,265

(22) PCT Filed: Mar. 28, 2011
(86) PCT No.: PCT/JP2011/001833

§ 371 Date: Jun. 21, 2012

(30) Foreign Application Priority Data
Apr. 9, 2010 (JP) 2010-090670

(51) Int. Cl. H05B 33/12; G02F 1/1333

(52) U.S. Cl. 349/158; 313/504

(57) ABSTRACT

An organic EL display device (1) includes an organic substrate (2) and an organic EL display element (11) provided on the organic substrate (2). A honeycomb-shaped structural element (30) including a plurality of cells (30b) separated from each other by a cell wall (30a) is provided on a surface opposite to the organic EL display element (11) of the organic substrate (2).

### TECHNICAL FIELD

The present disclosure relates to display devices, such as organic EL display devices etc.

### BACKGROUND ART

In recent years, in the field of displays, considerable attention has been directed to thin display devices including an organic substrate etc. which has advantages over glass substrates in terms of flexibility, shock resistance, and light weight, i.e., potential novel displays which cannot be produced using a glass substrate.

For example, an organic EL display device has been described which includes a TFT substrate including data lines extending in a first direction and arranged side by side in a second direction, select lines extending in the second direction and arranged side by side in the first direction, and a TFT and an organic EL layer formed in each of regions surrounded by the data lines and the select lines, and can be curved in the second direction (see, for example, Patent Document 1).

### CITATION LIST

### Patent Document

PATENT DOCUMENT 1: Japanese Patent Publication No. 2009-48007

### SUMMARY OF THE INVENTION

### Technical Problem

Here, a display device typified by the organic EL display device of Patent Document 1 includes a thin film base material (thickness: about 100 μm, for example) made of polyimide resin etc. and therefore has flexibility. If the flexibility is high, the display device bends due to its own weight, so that deformation, such as warp, swell, etc., occurs in the display device. As a result, images displayed on the display device are disadvantageously less visible.

The high flexibility also causes the display device to be bent by external force, such as mechanical stress etc. In this case, due to being thus bent, stress is concentrated at a predetermined portion of the display device, so that the following problems may occur in the display device: damage, such as a crack etc.; disconnection due to a break in metal wiring; and destruction of a TFT element. In particular, if such a crack occurs in the manufacturing process, the yield of the display device is disadvantageously reduced.

Therefore, the present invention has been made in view of the above problem. It is an object of the present invention to provide a display device which has flexibility and satisfactory display performance, and in which the occurrence of damage (e.g., a crack etc.), disconnection due to a break in metal wiring, and destruction of a TFT element which are caused by bending is reduced or prevented, whereby the yield can be improved.

### Solution to the Problem

To achieve the object, a display device according to the present invention includes a substrate and a display element provided on the substrate. A structural element including a plurality of cells separated from each other by a cell wall is provided on a surface opposite to the display element of the substrate.

With this configuration, the stiffness of the display device can be improved, whereby the bending due to the own weight can be reduced or prevented, and therefore, the occurrence of deformation, such as warp, swell, etc. can be reduced or prevented in the display device. As a result, the display performance of the display device can be improved.

Because the bending due to the own weight can be reduced or prevented, even when the display device is held by grasping an end portion thereof, the display device sustains itself against the support at the end portion. Therefore, the self-sustaining capability of the display device can be improved.

Even if the display device is bent by external force, such as mechanical stress etc., stress can be dispersed by the cell wall of the structural element, whereby the concentration of the stress at a predetermined portion of the display device can be reduced or prevented. Therefore, the occurrence of damage (a crack etc.), disconnection due to a break in metal wiring, and destruction of a TFT element can be reduced or prevented in the display device, and a decrease in the yield of the display device can be reduced or prevented.

Even when the user intentionally applies stress to the display device, the display device can be deformed into a desired shape without the occurrence of damage (a crack etc.), disconnection due to a break in metal wiring, and destruction of a TFT element.

In the display device of the present invention, the cell wall may be made of a resin material or a metal material.

With this configuration, the structural element can be made of a low-cost and widely used material.

In the display device of the present invention, an adhesive layer may be provided on the surface of the substrate, and the structural element may be provided on the substrate with the adhesive layer being interposed therebetween.

With this configuration, the structural element can be provided on the substrate by a simple configuration.

In the display device of the present invention, the structural element may have a thickness of 10 μm to 1 mm

With this configuration, the stiffness of the display device can be sufficiently improved without an increase in the overall thickness and weight of the display device.

In the display device of the present invention, the structural element may be covered by a coating layer.

With this configuration, damage to the organic substrate to which the structural element is attached can be effectively reduced or prevented.

In the display device of the present invention, the cell wall may include a first cell wall extending in a bending direction of the display device and a second cell wall extending in a direction perpendicular to the bending direction.

With this configuration, if the display device is bent in a single direction, the second cell wall allows the display device to bend (e.g., bend into a roll shape) so that the display device is freely deformed in a direction desired by the user. Also, the state of bending of the display device can be held or maintained by the first cell wall. Therefore, the display device can have excellent display performance and can be easily viewed by the user.

In the display device of the present invention, the display performance can be improved, and the occurrence of damage (a crack etc.), disconnection due to a break in metal wiring, and destruction of a TFT element can be reduced or prevented, whereby a decrease in the yield of the display device can be reduced or prevented. Therefore, the present invention can be preferably applied to a display device including an organic EL display element as a display element. The present invention can also be preferably applied to a display device including a liquid crystal display element as a display element.

### Advantages of the Invention

According to the present invention, a display device can be provided in which flexibility and satisfactory display performance are provided, and the occurrence of damage (a crack etc.), disconnection due to a break in metal wiring, and destruction of a TFT element due to bending is reduced or prevented without impairing the thinness and lightweight, whereby the yield can be improved.

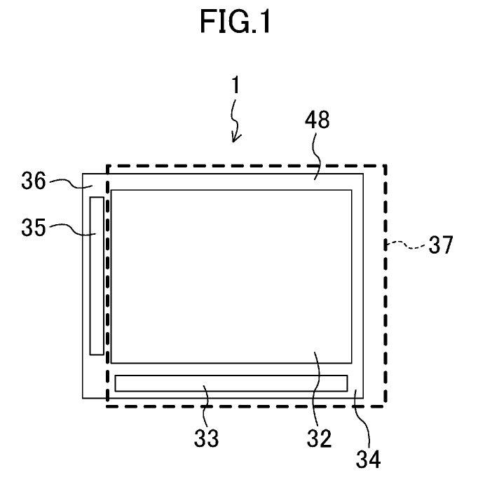

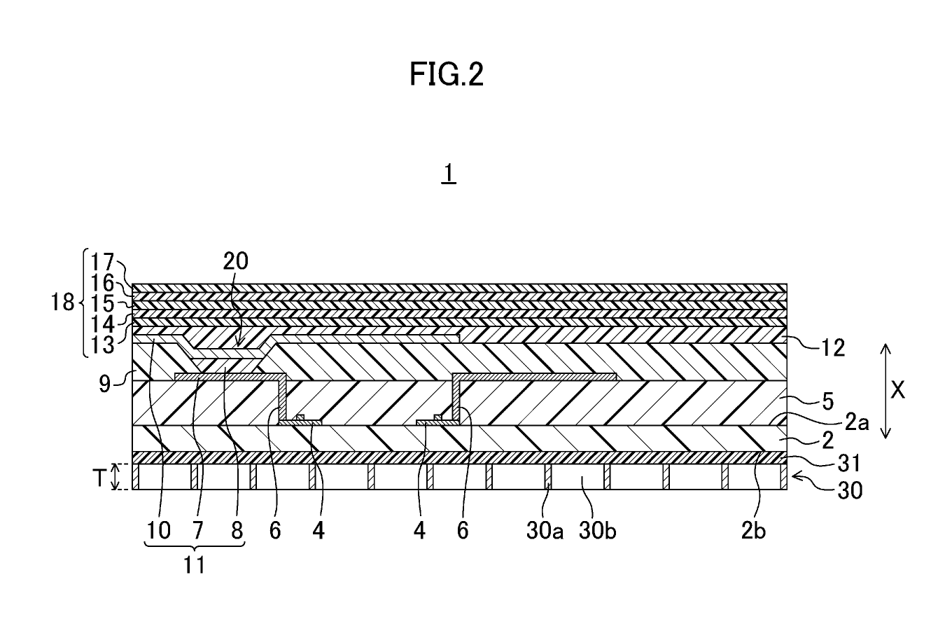

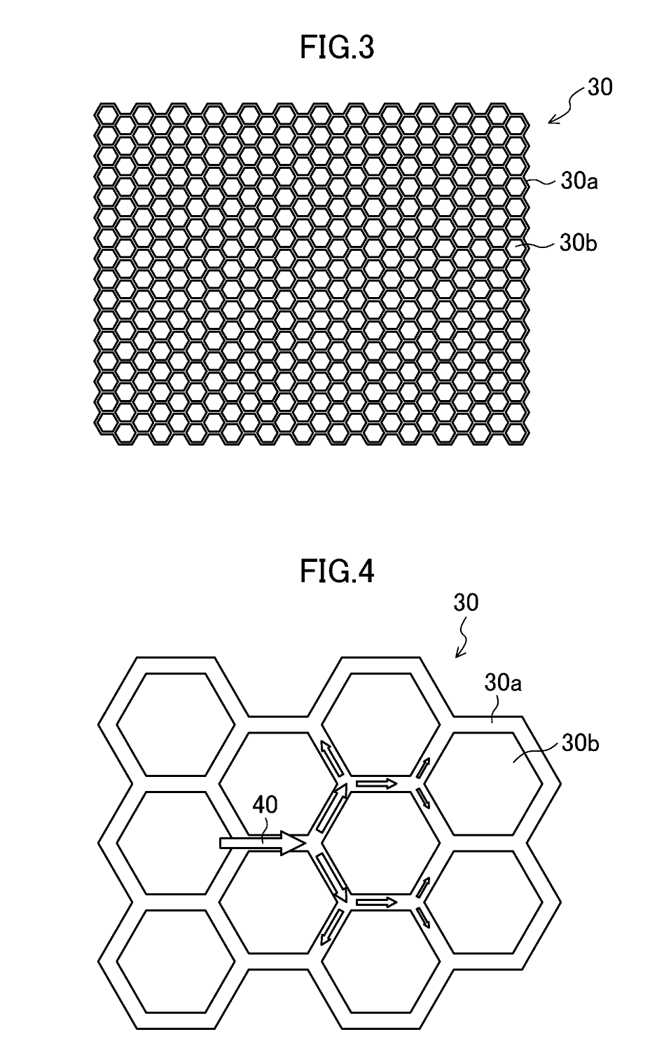

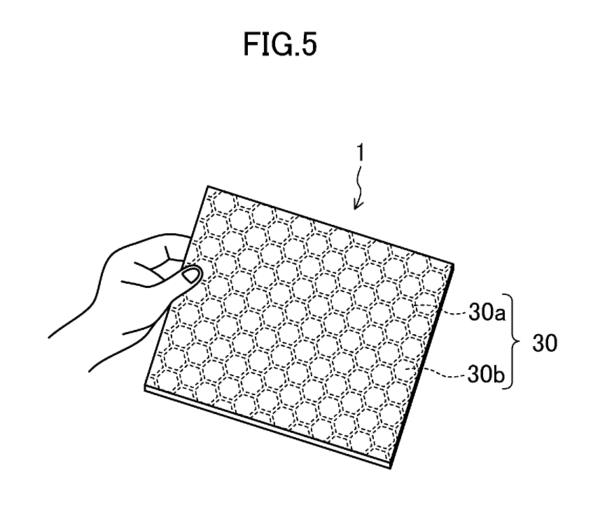

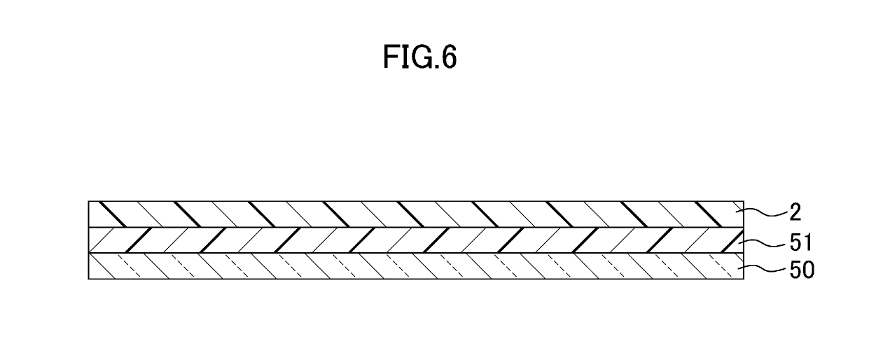

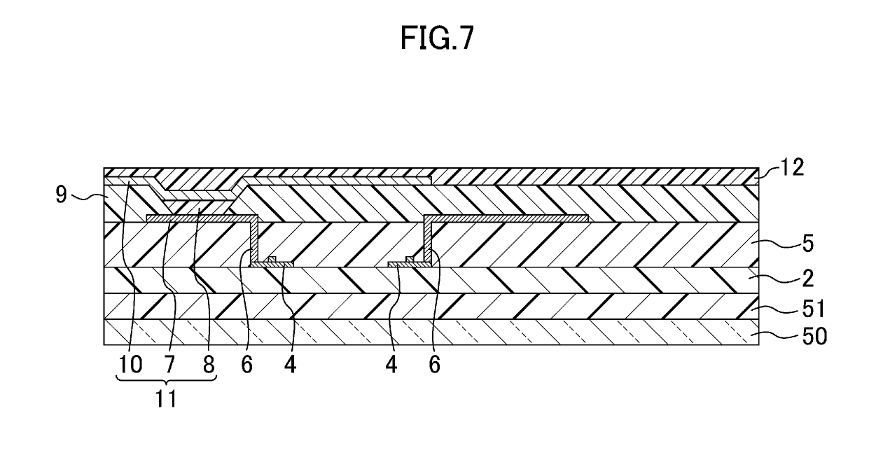

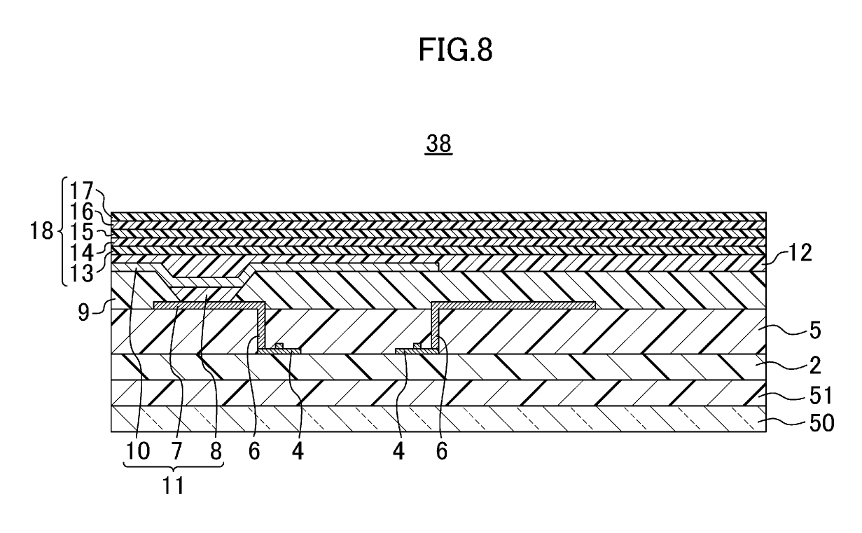

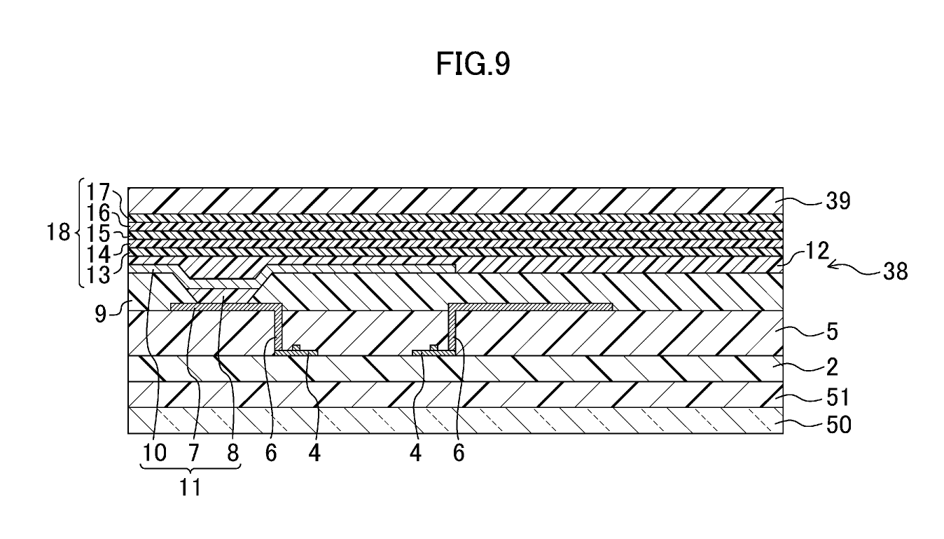

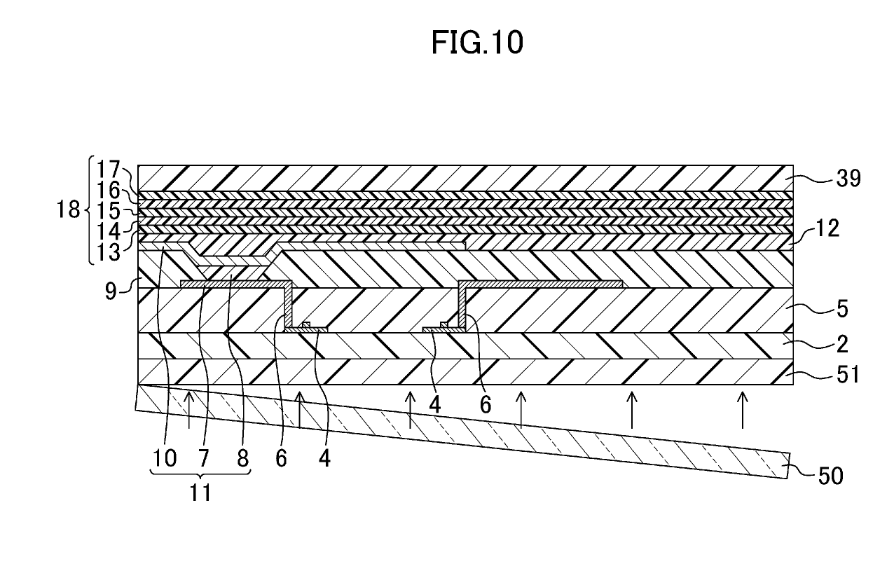

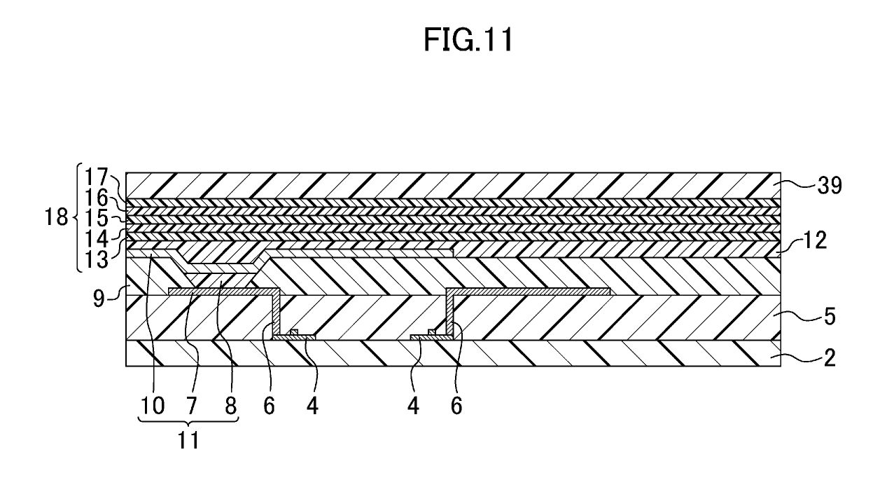

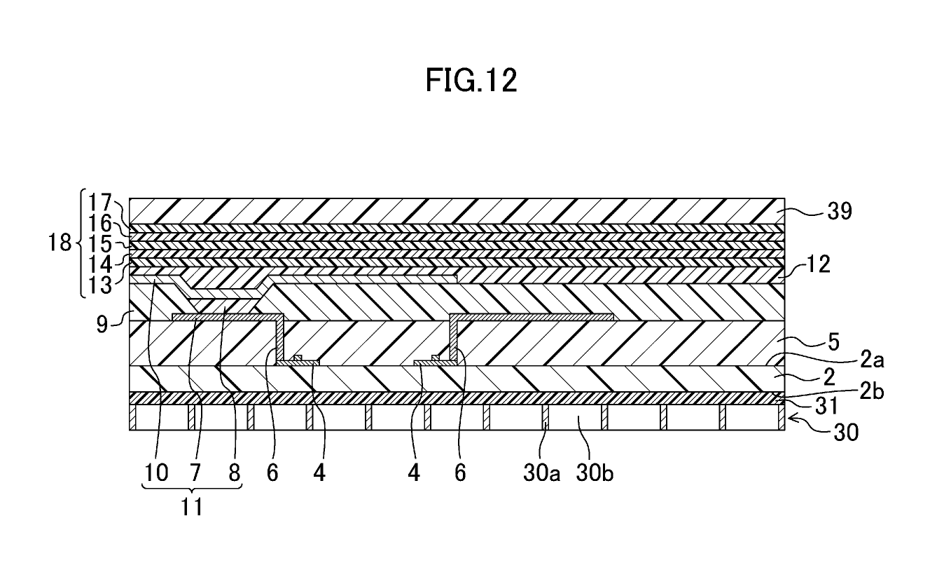

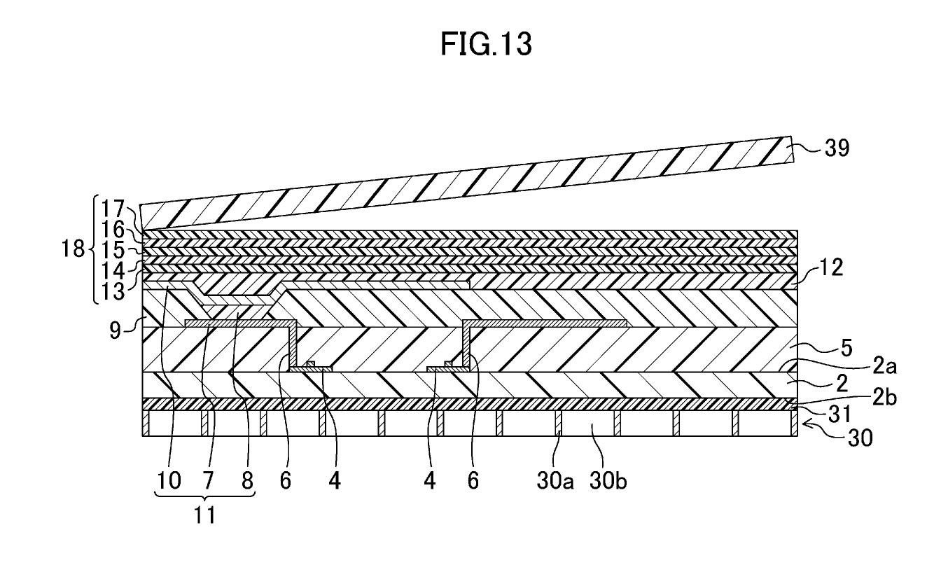

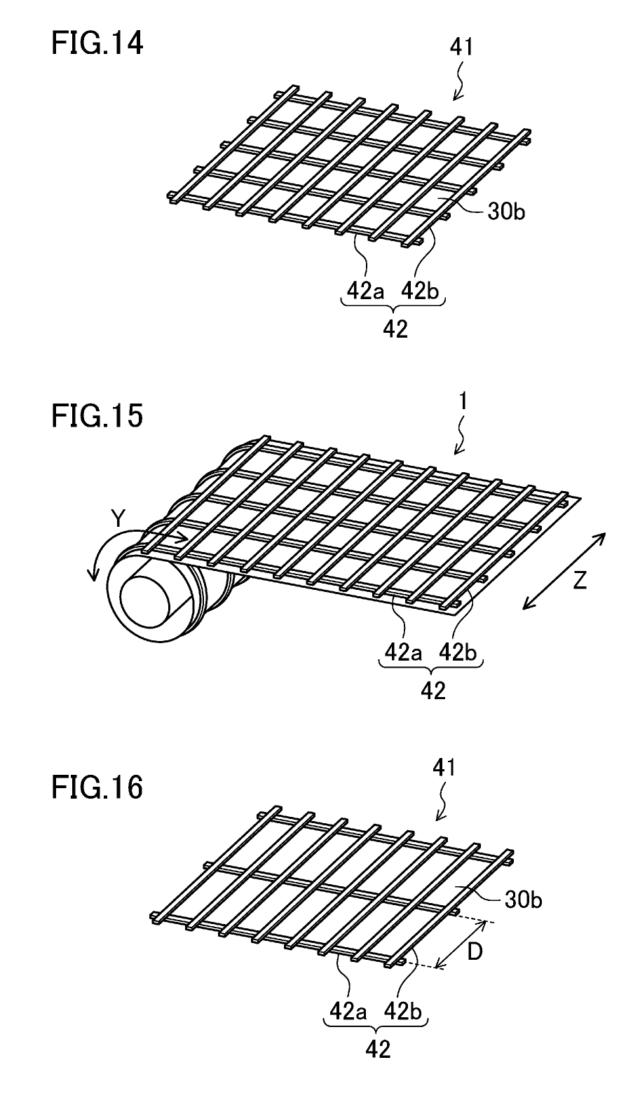

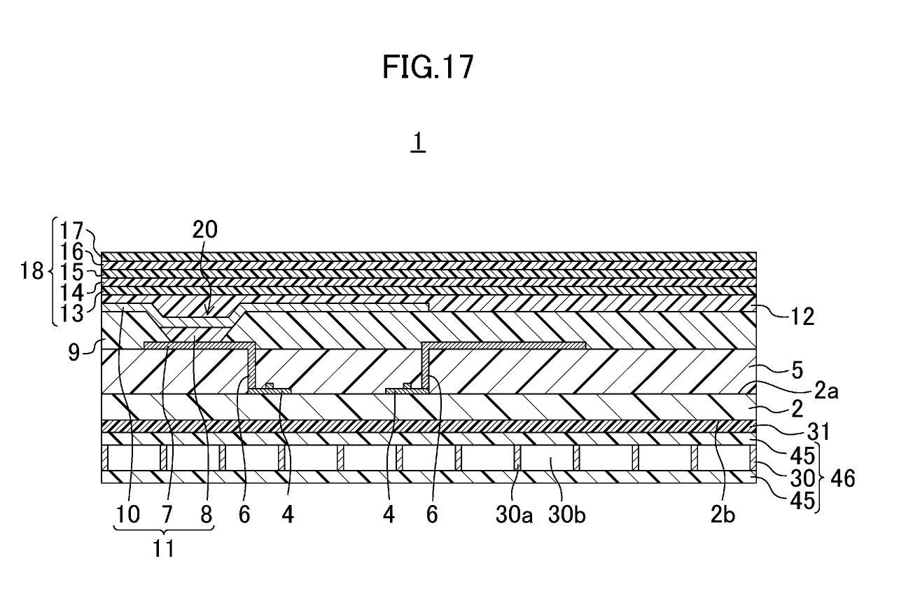

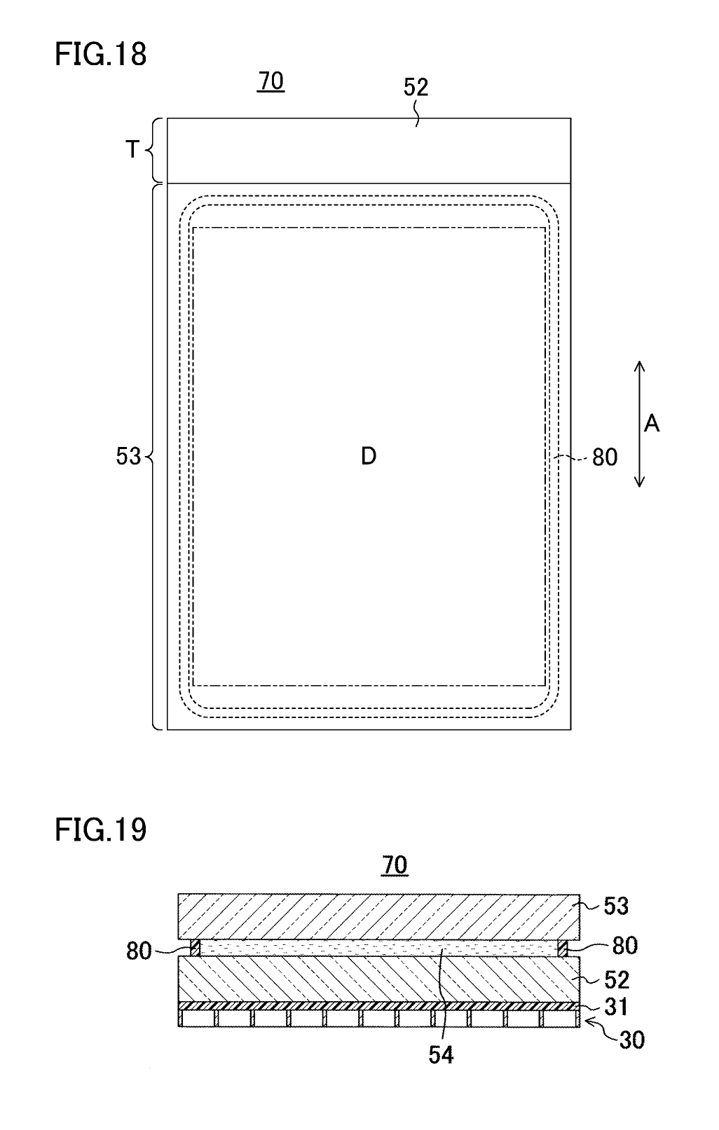

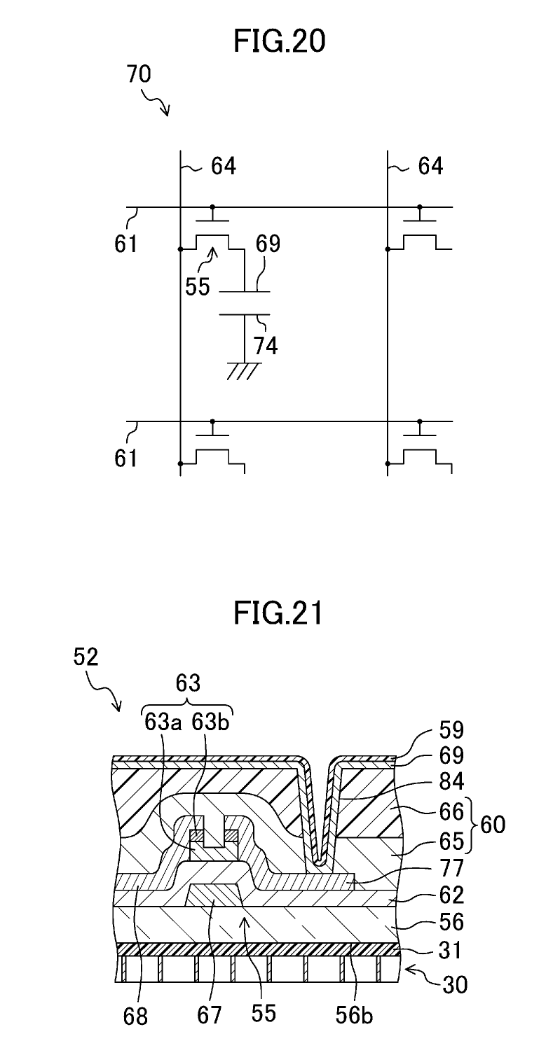

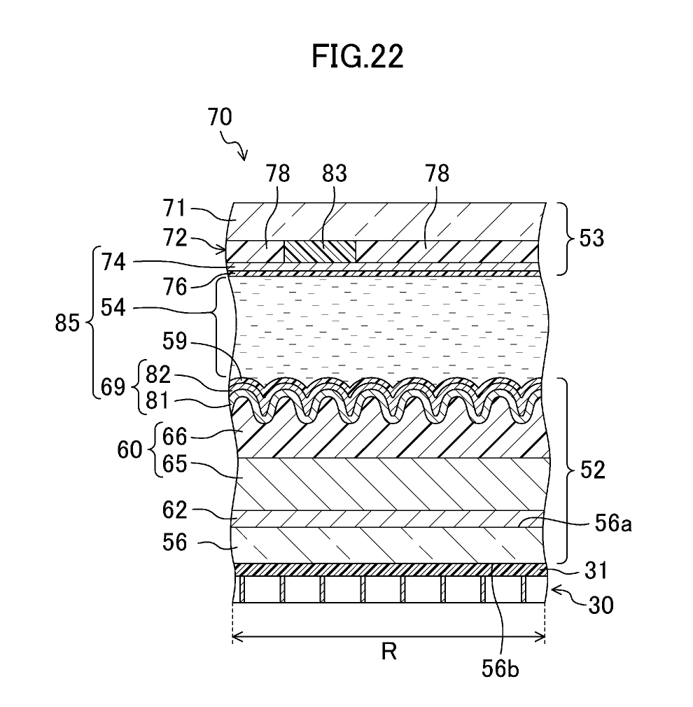

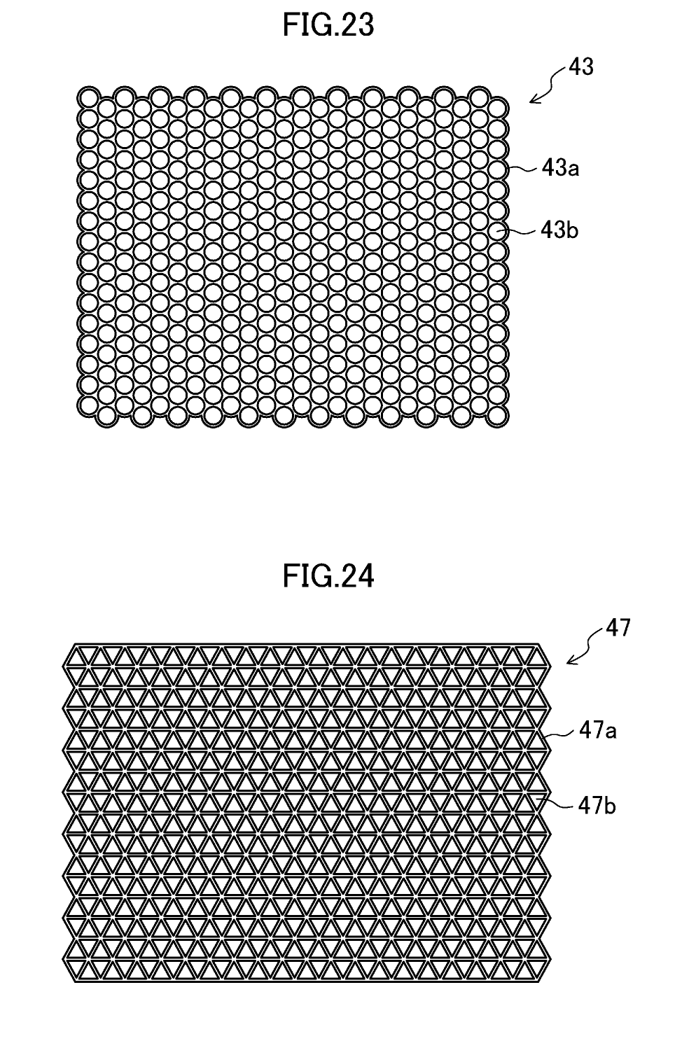

### BRIEF DESCRIPTION OF THE DRAWINGS

[FIG. 1] FIG. 1 is a plan view of an organic EL display device according to a first embodiment of the present invention.

[FIG. 2] FIG. 2 is a cross-sectional view of the organic EL display device of the first embodiment of the present invention.

[FIG. 3] FIG. 3 is a plan view showing a structural element in the organic EL display device of the first embodiment of the present invention.

[FIG. 4] FIG. 4 is an enlarged view of a portion of the structural element of FIG. 3.

[FIG. 5] FIG. 5 is a diagram showing the organic EL display device of the first embodiment of the present invention which is held by grasping an end portion thereof.

[FIG. 6] FIG. 6 is a cross-sectional view for describing a method for manufacturing the organic EL display device of the first embodiment of the present invention.

[FIG. 7] FIG. 7 is a cross-sectional view for describing the method for manufacturing the organic EL display device of the first embodiment of the present invention.

[FIG. 8] FIG. 8 is a cross-sectional view for describing the method for manufacturing the organic EL display device of the first embodiment of the present invention.

[FIG. 9] FIG. 9 is a cross-sectional view for describing the method for manufacturing the organic EL display device of the first embodiment of the present invention.

[FIG. 10] FIG. 10 is a cross-sectional view for describing the method for manufacturing the organic EL display device of the first embodiment of the present invention.

[FIG. 11] FIG. 11 is a cross-sectional view for describing the method for manufacturing the organic EL display device of the first embodiment of the present invention.

[FIG. 12] FIG. 12 is a cross-sectional view for describing the method for manufacturing the organic EL display device of the first embodiment of the present invention.

[FIG. 13] FIG. 13 is a cross-sectional view for describing the method for manufacturing the organic EL display device of the first embodiment of the present invention.

[FIG. 14] FIG. 14 is a perspective view showing a structural element in an organic EL display device according to a second embodiment of the present invention.

[FIG. 15] FIG. 15 is a perspective view showing the organic EL display device of the second embodiment of the present invention.

[FIG. 16] FIG. 16 is a diagram for describing a variation of the structural element of FIG. 14.

[FIG. 17] FIG. 17 is a cross-sectional view for describing a variation of the organic EL display device of the first embodiment of the present invention.

[FIG. 18] FIG. 18 is a plan view showing an entire configuration of a liquid crystal display device according to a third embodiment of the present invention.

[FIG. 19] FIG. 19 is a cross-sectional view of the liquid crystal display device of the third embodiment of the present invention.

[FIG. 20] FIG. 20 is a diagram showing an equivalent circuit of the liquid crystal display device of the third embodiment of the present invention.

[FIG. 21] FIG. 21 is a cross-sectional view showing an entire configuration of a TFT substrate included in the liquid crystal display device of the third embodiment of the present invention.

[FIG. 22] FIG. 22 is a cross-sectional view showing an entire configuration of a display unit of the liquid crystal display device of the third embodiment of the present invention.

[FIG. 23] FIG. 23 is a plan view for describing a variation of the structural element of the present invention.

[FIG. 24] FIG. 24 is a plan view for describing a variation of the structural element of the present invention.

### DESCRIPTION OF EMBODIMENTS

### First Embodiment

A display device according to an embodiment of the present invention will be described in detail hereinafter with reference to the accompanying drawings. Note that the present invention is not intended to be limited to the embodiment described below. In this embodiment, an organic EL display device will be described as an example of the display device.

FIG. 1 is a plan view of an organic EL display device according to a first embodiment of the present invention. FIG. 2 is a cross-sectional view of the organic EL display device of the first embodiment of the present invention. FIG. 3 is a plan view showing a structural element in the organic EL display device of the first embodiment of the present invention. FIG. 4 is an enlarged view of a portion of the structural element of FIG. 3.

As shown in FIG. 1, the organic EL display device 1 includes, for example, a display region 32 formed of a plurality of pixels etc., and a peripheral circuit region 48 provided around the display region 32.

The peripheral circuit region 48 includes a drive circuit region 34 in which a driver unit 33 is provided, and a terminal region 36 in which an interconnect terminal 35 is extended from the display region 32.

The organic EL display device 1 also includes a film-like organic substrate 2 having flexibility which is formed of a transparent and colorless resin film deposited at room temperature. The organic substrate 2 may be made of, for example, an organic material, such as poly-para-xylene resin, acrylic resin, polyimide resin, etc. Note that a metal substrate having flexibility may be used instead of the organic substrate.

The organic substrate 2 preferably has a thickness of 3-20 μm. This is because a sufficient mechanical strength may not be obtained if the thickness is less than 3 μm, and the flexibility of the organic EL display device 1 may be low if the thickness is more than 20 μm.

A gate driver or a source driver corresponding to the driver unit 33 of FIG. 1 may be implemented in a monolithic form if a TFT made of polysilicon is employed as a TFT element. As described above, the organic EL display device 1 includes the film-like organic substrate 2 made of poly-para-xylene resin etc., and therefore, a large region indicated by a dashed-line frame 37 of FIG. 1 has satisfactory flexibility, for example.

The flexible region is not limited to the region indicated by the dashed-line frame 37 of FIG. 1, and may be formed to have a desired range by adjusting the configuration of the film substrate, etc.

Note that a flexible printed wiring board (not shown) connected to the interconnect terminal 35 is provided in the terminal region 36 of FIG. 1. The flexible printed wiring board is also connected to an IC unit (not shown) for driving the organic EL display device 1.

As shown in FIG. 2, in the organic EL display device 1 of this embodiment, a display element layer including TFT elements 4 etc. is formed on the organic substrate 2. The display element layer includes the TFT elements 4 formed on the organic substrate 2, an interlayer insulating film 5 (e.g., a SiO₂ film, a SiN film, etc.) covering the TFT elements 4, and metal interconnects 6 penetrating the interlayer insulating film 5 to electrically connect to the TFT elements 4.

The metal interconnect 6 is further extended on the interlayer insulating film 5 to form a first electrode 7 of an organic EL display element 11.

An insulating film (or a bank) 9 for separating pixels (regions) 20 from each other is formed on the interlayer insulating film 5. The insulating film 9 may be made of, for example, an insulating resin material, such as photosensitive polyimide resin, acrylic resin, methacrylic resin, novolac resin, etc. Note that the interlayer insulating film 5 may have a thickness of, for example, 0.5-1 μm. The insulating film 9 may have a thickness of, for example, 2-4 μm.

The organic EL display device 1 is of bottom emission type, in which light is extracted from the side on which the first electrode 7 is provided. Therefore, in order to improve the efficiency of extraction of light, the first electrode 7 is preferably formed of a thin film made of a material which has a high work function and a high light transmittance, such as ITO, SnO₂, etc.

An organic EL layer 8 is formed on the first electrode 7. The organic EL layer 8 includes a hole transport layer and a light emitting layer. The hole transport layer is not limited if the hole transport layer has a high hole injection efficiency. The hole transport layer may be made of, for example, an organic material, such as a triphenylamine derivative, a poly(para-phenylene vinylene) (PPV) derivative, a polyfluorene derivative, etc.

The light emitting layer may be made of, for example but not limited to, an 8-hydroxyxyquinoline derivative, a thiazole derivative, or a benzoxazole derivative, etc. Two or more of these materials may be combined together, or these materials may be combined with an addative, such as a dopant material etc.

While the organic EL layer 8 has been illustrated to have a two-layer structure including a hole transport layer and a light emitting layer, the configuration of the organic EL layer 8 is not limited to this. Alternatively, the organic EL layer 8 may have a single-layer structure including only a light emitting layer. Alternatively, the organic EL layer 8 may include one or more of a hole transport layer, a hole injection layer, an electron injection layer, and an electron transport layer, and a light emitting layer.

A second electrode 10 is formed on the organic EL layer 8 and the insulating film 9. The second electrode 10 has a function of injecting electrons into the organic EL layer 8. While the second electrode 10 may be formed of a thin film made of, for example, Mg, Li, Ca, Ag, Al, In, Ce, or Cu, etc., the material of the second electrode 10 is not limited to these.

The first electrode 7, the organic EL layer 8 formed on the first electrode 7 and including the light emitting layer, and the second electrode 10 formed on the organic EL layer 8 constitute the organic EL display element 11.

In the organic EL display device 1, the first electrode 7 has a function of injecting holes into the organic EL layer 8, and the second electrode 10 has a function of injecting electrons into the organic EL layer 8. Holes injected from the first electrode 7 and electrons injected from the second electrode 10 recombine in the organic EL layer 8, whereby light is emitted from the organic EL layer 8. Because the organic substrate 2 and the first electrode 7 can transmit light and the second electrode 10 can reflect light, emitted light is transmitted through the first electrode 7 and the organic substrate 2 to be extracted from the organic EL layer 8 (bottom emission type).

A planarization film 12 made of acrylic resin or polyparaxylene resin, etc. is formed on the second electrode 10. Note that the planarization film 12 may have a thickness of, for example, 3-8 μm.

A sealing film 18 having a multilayer structure including resin films 13, 15, and 17, an inorganic film 14, and a metal oxide film 16 is formed on the planarization film 12. The resin films 13, 15, and 17 may be made of a resin material similar to that of the planarization film 12, or may be made of other resin materials. The inorganic film 14 and the metal oxide film 16 may be made of, for example, SiNₓ, SiO₂, or Al₂O₃, etc.

Note that the number of the resin films and the number of inorganic films in the sealing film 18 may not be two or more as described above, and the sealing film 18 may include only one resin film and only one inorganic film. The sealing film 18 may include a metal thin film. The sealing film 18 may have a thickness of, for example, 1-5 μm.

The TFT element 4 may be a TFT made of, for example, amorphous silicon which is used as a channel. The TFT element 4, which is amorphous, has a lower carrier (electrons etc.) mobility than that of a TFT element made of polysilicon, but can provide a display device having a large screen (i.e., a large display region).

Note that the TFT element 4 may be a TFT which includes an oxide semiconductor layer formed of an IGZO (In—Ga—Zn—O) oxide semiconductor film, which has high mobility, instead of the semiconductor layer made of amorphous silicon.

Thus, in the organic EL display device 1, the TFT element 4 which is a switching element for the pixel 20, and the organic EL display element 11, are formed on the film-like organic substrate 2.

Here, in the organic EL display device 1 of this embodiment, as shown in FIG. 2, a honeycomb-shaped structural element 30 is provided on a surface 2b opposite to the organic EL display element 11 of the organic substrate 2. More specifically, the honeycomb-shaped structural element 30 which improves the stiffness of the organic EL display device 1 is provided on the surface 2b of the organic substrate 2 opposite to a surface 2a on which the organic EL display element 11 is provided.

Such a configuration can improve the stiffness of the organic EL display device 1. Therefore, the bending due to the own weight can be reduced or prevented, whereby the occurrence of deformation, such as warp, swell, etc., can be reduced or prevented in the organic EL display device 1. As a result, the display performance of the organic EL display device 1 can be improved.

Because the bending due to the own weight can be reduced or prevented, even when the organic EL display device 1 is held by grasping an end portion thereof as shown in FIG. 5, the organic EL display device 1 sustains itself (i.e., does not bend or deform) against the support at the end portion. Therefore, the self-sustaining capability of the organic EL display device 1 can be improved.

Even if the organic EL display device 1 is bent by external force, such as mechanical stress etc., as shown in FIG. 4 a cell wall 30a of the honeycomb-shaped structural element 30 can disperse stress 40. Specifically, the stress 40 occurring when the organic EL display device 1 is bent is propagated through the cell wall 30a to disperse, whereby the concentration of the stress at a predetermined portion of the organic EL display device 1 can be reduced or prevented. Therefore, the occurrence of damage (a crack etc.), disconnection due to a break in metal wiring, and destruction of the TFT element 4 can be reduced or prevented in the organic EL display device 1, and a decrease in the yield of the organic EL display device 1 can be reduced or prevented.

Also, even when the user intentionally applies stress to the organic EL display device 1, the organic EL display device 1 can be deformed into a desired shape without the occurrence of damage (a crack etc.), disconnection due to a break in metal wiring, and destruction of the TFT element 4.

As shown in FIG. 2, the honeycomb-shaped structural element 30 is stacked on the surface 2b of the organic substrate 2 with an adhesive layer 31 being interposed therebetween.

As shown in FIGS. 2 and 3, the honeycomb-shaped structural element 30 includes the cell wall (separation wall) 30a, and a plurality of cells (space portions) 30b which are separated from each other by the cell wall 30a and penetrate in a thickness direction (i.e., a thickness direction of the organic EL display device 1, or a direction indicated by an arrow X in FIG. 2) of the honeycomb-shaped structural element 30.

In this embodiment, as shown in FIGS. 3 and 4, the cell wall 30a of the honeycomb-shaped structural element 30 is arranged in the shape of substantially a hexagon in cross-section. Similarly, as shown in FIGS. 3 and 4, the cells 30b separated from each other by the cell wall 30a each have the shape of substantially a hexagon in cross-section.

The cell wall 30a of the honeycomb-shaped structural element 30 may be made of any material that can improve the stiffness of the organic EL display device 1 and impart flexibility to the honeycomb-shaped structural element 30. In this embodiment, examples of such a material include resin materials, such as polyethylene terephthalate resin, polyethylene naphthalate resin, acrylic resin, polycarbonate resin, etc., and metal materials, such as stainless steel, iron, aluminum, titanium, nickel, chromium, molybdenum, tantalum, or alloys thereof.

The honeycomb-shaped structural element 30 preferably has a thickness of 10 μm to 1 mm, more preferably 50-500 μm. This is because the stiffness of the organic EL display device 1 may not be sufficiently improved if the thickness is less than 10 μm, and the thickness and weight of the organic EL display device 1 may be disadvantageously large if the thickness is more than 1 mm.

Note that the thickness of the honeycomb-shaped structural element 30 is determined, depending on how a product employing the honeycomb-shaped structural element 30 is used, the Young's modulus or weight of the material of the honeycomb-shaped structural element 30, etc.

An adhesive included in the adhesive layer 31 is not particularly limited. Examples of the adhesive include various resin-based adhesives, such as epoxy resin, butyral resin, acrylic resin, etc.

Next, a method for manufacturing the organic EL display device of the embodiment of the present invention will be described. FIGS. 6-13 are cross-sectional views for describing the method for manufacturing the organic EL display device of the embodiment of the present invention. Note that the manufacturing method described below is only for illustrative purposes. The organic EL display device of the present invention is not limited to those manufactured by the method described below.

Initially, as shown in FIG. 6, as a support substrate, a glass substrate 50 having a thickness of about 0.7 mm is prepared, for example.

Next, as shown in FIG. 6, on the glass substrate 50, a sacrificial film 51 is formed which is made of, for example, a resin material having a heat resistance temperature (or a glass transition temperature) of 400° C. or more and a thermal expansion coefficient of 10 ppm/° C. or less, and has a thickness of, for example, about 0.1-1 μm. The resin material for the sacrificial film 51 which meets the above conditions may be, for example, polyimide resin. Note that the sacrificial film 51 is used to satisfactorily remove or detach the glass substrate 50.

Next, in the case of a transmissive display element, the film-like organic substrate 2 formed of a transparent resin film and having a thickness of, for example, about 5 μm is formed on the sacrificial film 51. Examples of the resin material for the organic substrate 2 include polyimide resin, fluorene epoxy resin, and fluorocarbon resin. In this embodiment, the organic substrate 2 is formed by applying resin to a surface of the sacrificial film 51. Note that, in the case of a reflective display element or a top-emission light-emission display element, if the organic substrate 2 is made of the same resin material as that of the sacrificial film 51, the sacrificial film may be removed. The organic substrate 2 may be attached to the glass substrate 50.

Next, as shown in FIG. 7, the TFT element 4 which is a switching element for the pixel 20 is formed by forming a metal film, a semiconductor film etc. on the organic substrate 2 and patterning, etc.

Next, the interlayer insulating film 5 formed of, for example, a SiO₂ film or a SiN film etc. and having a thickness of about 1-2 μm is formed on the organic substrate 2 on which the TFT element 4 has been formed.

Next, a contact hole which extends from a surface of the interlayer insulating film 5 to the TFT element 4 is provided. The metal interconnect 6 electrically connecting to the TFT element 4 is made of a transparent conductive material, such as ITO etc. The first electrode 7 having a thickness of, for example, about 150 nm is formed by patterning etc.

Next, the insulating film 9 having a thickness of, for example, about 3 μm is formed on the interlayer insulating film 5, and thereafter, a portion of the insulating film 9 corresponding to the first electrode 7 is removed by etching.

Next, a hole transport layer and a light emitting layer are formed on the first electrode 7 to provide the organic EL layer 8. The hole transport layer is formed as follows: initially, a hole transport material coating which is obtained by dissolving or dispersing, in a solvent, an organic polymer material which is a hole transport material, is supplied onto the exposed first electrode 7 using, for example, an inkjet technique etc; and thereafter, baking is performed. Next, the light emitting layer is formed as follows: an organic light emission material coating which is obtained by dissolving or dispersing, in a solvent, an organic polymer material which is a light emission material, is supplied to cover the hole transport layer using, for example, an inkjet technique etc.; and thereafter, baking is performed.

Next, the second electrode 10 made of Mg, Li, Ca, Ag, Al, In, Ce, or Cu, etc. is formed on the insulating film 9 and the organic EL layer 8 by sputtering etc. The second electrode 10 has a thickness of, for example, about 150 nm As a result, the organic EL display element 11 is formed which includes the first electrode 7, the organic EL layer 8 formed on the first electrode 7 and including a light emitting layer, and the second electrode 10 formed on the organic EL layer 8.

Next, a TEOS film or a SiN film etc. is formed on the second electrode 10, and a surface of the film is polished by chemical mechanical polishing (CMP) etc. to form the planarization film 12.

Next, as shown in FIG. 8, the resin film 13, the inorganic film 14, the resin film 15, the metal oxide film 16, and the resin film 17 are formed on the planarization film 12 successively in this order to form the sealing film 18. Thus, a multilayer arrangement 38 is fabricated. The resin films 13, 15, and 17 are each made of, for example, poly-para-xylene resin etc. and each have a thickness of about 5 μm. The inorganic film 14 and the metal oxide film 16 are each made of, for example, SiNₓ, SiO₂, or Al₂O₃, etc. and each have a thickness of about 500 nm

Next, as shown in FIG. 9, the multilayer arrangement 38 thus fabricated is transferred to a transfer film 39. Note that the transfer film 39 may be formed of, for example, a release film whose adhesiveness is lowered by a UV or thermal treatment.

Next, as shown in FIG. 10, the glass substrate 50 is removed or detached by being irradiated with laser light from the bottom (the glass substrate 50 side) (as indicated by an arrow in FIG. 10).

Here, the removal of the glass substrate 50 is not limited to the detachment by laser irradiation. The glass substrate 50 may be removed using, for example, a polishing device or an etching device.

Next, as shown in FIG. 11, the sacrificial film 51 which has been exposed by the removal of the glass substrate 50 is removed by plasma etching. Here, the removal of the sacrificial film 51 is not limited to plasma etching. Alternatively, the sacrificial film 51 may be removed by, for example, microwave plasma etching. Note that, in the case of a reflective display element or a top-emission light-emission display element, it is not necessary to etch the sacrificial film 51.

Next, as shown in FIG. 12, the cell wall 30a made of polyethylene terephthalate resin or stainless steel etc. is attached via the adhesive layer 31 to the surface 2b of the organic substrate 2 opposite to the surface 2a on which the organic EL display element 11 is provided, to form the honeycomb-shaped structural element 30 having a thickness of, for example, 150 μm.

Next, as shown in FIG. 13, the transfer film 39 is removed from the surface of the sealing film 18. Thus, the organic EL display device 1 of FIG. 2 can be manufactured.

According to this embodiment described above, the following advantages can be obtained.

(1) In this embodiment, the honeycomb-shaped structural element 30 including the cells 30b separated from each other by the cell wall 30a is provided on the surface of the organic substrate 2 opposite to the organic EL display element 11. Therefore, the stiffness of the organic EL display device 1 can be improved, whereby the bending due to the own weight can be reduced or prevented, and therefore, the occurrence of deformation, such as warp, swell, etc. can be reduced or prevented in the organic EL display device 1. As a result, the display performance of the organic EL display device 1 can be improved.

(2) The reduction or prevention of the bending due to the own weight improves the self-sustaining capability of the organic EL display device 1.

(3) Even if the organic EL display device 1 is bent by external force, such as mechanical stress etc., the stress 40 can be dispersed by the cell wall 30a of the honeycomb-shaped structural element 30, whereby the concentration of the stress at a predetermined portion of the organic EL display device 1 can be reduced or prevented. Therefore, the occurrence of damage (a crack etc.), disconnection due to a break in metal wiring, and destruction of the TFT element 4 can be reduced or prevented in the organic EL display device 1, and a decrease in the yield of the organic EL display device 1 can be reduced or prevented.

(4) Even when the user intentionally applies stress to the organic EL display device 1, the organic EL display device 1 can be deformed into a desired shape without the occurrence of damage (a crack etc.), disconnection due to a break in metal wiring, and destruction of the TFT element 4.

(5) In this embodiment, the cell wall 30a is made of a resin material or a metal material. Therefore, the honeycomb-shaped structural element 30 can be made of a low-cost and widely used material.

(6) In this embodiment, the adhesive layer 31 is provided on the surface 2b of the organic substrate 2, and the honeycomb-shaped structural element 30 is provided on the organic substrate 2 with the adhesive layer 31 being interposed therebetween. Therefore, the honeycomb-shaped structural element 30 can be provided on the organic substrate 2 by the simple configuration.

(7) In this embodiment, the thickness of the honeycomb-shaped structural element 30 is set to 10 μm to 1 mm Therefore, the stiffness of the organic EL display device 1 can be sufficiently improved without an increase in the overall thickness and weight of the organic EL display device 1.

### Second Embodiment

Next, a second embodiment of the present invention will be described. FIG. 14 is a perspective view showing a structural element in an organic EL display device according to the second embodiment of the present invention. FIG. 15 is a perspective view showing the organic EL display device of the second embodiment of the present invention. Note that parts similar to those of the first embodiment are indicated by the same reference characters and will not be redundantly described. In this embodiment, the organic EL display device will be described as an example display device. A method for manufacturing the organic EL display device is similar to that of the first embodiment and will not be described in detail.

In this embodiment, as shown in FIGS. 14 and 15, a grid-shaped structural element 41 is provided instead of the honeycomb-shaped structural element 30. A cell wall 42 of the grid-shaped structural element 41 includes a first cell wall 42a extending in a bending direction (a direction indicated by an arrow Y in FIG. 15) of the organic EL display device 1 and a second cell wall 42b extending in a direction (a direction indicated by an arrow Z in FIG. 15) perpendicular to the bending direction Y.

With this configuration, if the organic EL display device 1 is bent in a single direction, the second cell wall 42b extending in the direction Z perpendicular to the bending direction Y of FIG. 15 allows the organic EL display device 1 to easily bend (e.g., bend into a roll shape as shown in FIG. 15) so that the organic EL display device 1 is freely deformed in a direction (i.e., the bending direction Y) desired by the user, and also reduces or prevents the bending of the organic EL display device 1 in the direction Z perpendicular to the bending direction Y.

The first cell wall 42a extending in the bending direction Y improves the self-sustaining capability of the organic EL display device 1 bending in the bending direction Y, whereby the state of bending of the organic EL display device 1 can be held or maintained. As a result, the organic EL display device 1 can be easily bent in a single direction and is difficult to bend in a plurality of directions. Thus, the organic EL display device 1 can be deformed into a shape desired by the user, and can have excellent display performance and can be easily viewed by the user.

Note that the capability to maintain the flexibility (bending capability) and the state of bending in the bending direction Y of the organic EL display device 1 can be adjusted by appropriately changing the material or thickness of each of the first and second cell walls 42a and 42b.

Alternatively, the capability to maintain the flexibility (bending capability) and the state of bending in the bending direction Y of the organic EL display device 1 may be adjusted by changing a distance between each first cell wall 42a (or a distance between each second cell wall 42b) and thereby changing a shape of the cells 30b.

For example, in order to improve the flexibility in the bending direction Y, as shown in FIG. 16 the distance D between each first cell wall 42a may be increased compared to the state of FIG. 14.

According to this embodiment described above, the following advantages can be obtained in addition to those of (1)-(7).

(8) In this embodiment, the cell wall 42 includes the first cell wall 42a extending in the bending direction Y and the second cell wall 42b extending in the direction Z perpendicular to the bending direction Y. Therefore, the second cell wall 42b allows the organic EL display device 1 to bend so that the organic EL display device 1 is freely deformed in a direction desired by the user. The first cell wall 42a improves the self-sustaining capability of the organic EL display device 1 bending in the bending direction Y, whereby the state of bending of the organic EL display device 1 can be held or maintained. As a result, the organic EL display device 1 can have excellent display performance and can be easily viewed by the user.

### Third Embodiment

FIG. 18 is a plan view showing an entire configuration of a liquid crystal display device according to a third embodiment of the present invention. FIG. 19 is a cross-sectional view of the liquid crystal display device of the third embodiment of the present invention. FIG. 20 is a diagram showing an equivalent circuit of the liquid crystal display device of the third embodiment of the present invention. FIG. 21 is a cross-sectional view showing an entire configuration of a TFT substrate included in the liquid crystal display device of the third embodiment of the present invention. FIG. 22 is a cross-sectional view showing an entire configuration of a display unit included in the liquid crystal display device of the third embodiment of the present invention. Note that, in this embodiment, the liquid crystal display device will be described as an example display device.

As shown in FIGS. 18 and 19, the liquid crystal display device 70 includes a TFT substrate (first substrate) 52 and a CF substrate (second substrate) 53 facing the TFT substrate 52. The liquid crystal display device 70 also includes a liquid crystal layer (display medium layer) 54 which is interposed between the TFT substrate 52 and the CF substrate 53, and a sealing member 80 which is interposed between the TFT substrate 52 and the CF substrate 53, attaches the TFT substrate 52 and the CF substrate 53 together, and is in the shape of a frame to enclose the liquid crystal layer 54.

The sealing member 80 is formed to surround the liquid crystal layer 54. The TFT substrate 52 and the CF substrate 53 are attached to each other via the sealing member 80. The liquid crystal display device 70 also includes a plurality of photospacers (not shown) for determining a thickness (i.e., a cell gap) of the liquid crystal layer 54.

As shown in FIG. 18, the liquid crystal display device 70 is in the shape of a rectangle. The TFT substrate 52 protrudes from the CF substrate 53 at the upper side thereof in a longitudinal direction A of the liquid crystal display device 70. In the protruding region, a terminal region T is provided in which a plurality of interconnects for displaying, such as gate lines, source lines, etc. (described below), are extended.

In the liquid crystal display device 70, a display region D where an image is to be displayed is provided in a region where the TFT substrate 52 and the CF substrate 53 overlap. Here, the display region D includes a plurality of pixels (the smallest unit of an image) arranged in a matrix.

As shown in FIG. 18, the sealing member 80 is in the shape of a rectangular frame which surrounds an entire perimeter of the display region D. The sealing member 80 has a frame width of, for example but not limited to, 0.5 mm or more and 2.0 mm or less.

As shown in FIGS. 20 and 21, the TFT substrate 52 includes an insulating substrate 56, such as a glass substrate etc., a plurality of gate lines 61 provided on the insulating substrate 56, extending in parallel to each other, and a gate insulating film 62 covering the gate lines 61. The TFT substrate 52 also includes a plurality of source lines 64 provided on the gate insulating film 62, extending in parallel to each other and in a direction perpendicular to the gate lines 61, and a plurality of TFT elements 55 provided at respective corresponding interconnections of the gate lines 61 and the source lines 64. The TFT substrate 52 also includes an interlayer insulating film 60 including a first interlayer insulating film 65 and a second interlayer insulating film 66 which are successively provided to cover the source lines 64 and the TFT elements 55, a plurality of pixel electrodes 69 provided and arranged in a matrix on the second interlayer insulating film 66 and connected to the respective corresponding TFT elements 55, and an alignment film 59 covering the pixel electrodes 69.

As shown in FIG. 21, the TFT element 55 includes a gate electrode 67 which is a laterally protruding portion of the gate line 61, the gate insulating film 62 covering the gate electrode 67, and an island-like semiconductor layer 63 on the gate insulating film 62 over the gate electrode 67. The TFT element 55 also includes a source electrode 68 and a drain electrode 77 which are provided on the semiconductor layer 63, facing each other. Here, the source electrode 68 is a laterally protruding portion of the source line 64. As shown in FIG. 21, the drain electrode 77 is connected to the pixel electrode 69 via a contact hole 84 formed in the first and second interlayer insulating films 65 and 66. As shown in FIG. 22, the pixel electrode 69 includes a transparent electrode 81 provided on the second interlayer insulating film 66, and a reflective electrode 82 provided on a surface of the transparent electrode 81. As shown in FIG. 21, the semiconductor layer 63 includes an intrinsic amorphous silicon layer (lower layer) 63a and an n⁺ amorphous silicon layer (upper layer) 63b doped with phosphorus. The intrinsic amorphous silicon layer 63a exposed from the source electrode 68 and the drain electrode 77 forms a channel region.

As shown in FIG. 22, in the display unit of the liquid crystal display device 70, the reflective electrode 82 determines a reflective region R. As shown in FIG. 22, the second interlayer insulating film (lower layer) 66 of the pixel electrode 69 has an uneven surface, and therefore, the reflective electrode 82 provided on the surface of the second interlayer insulating film 66 with the transparent electrode 81 being interposed therebetween also has an uneven surface.

Note that the first interlayer insulating film 65 is made of, for example but not limited to, silicon oxide (SiO₂) or silicon oxide (SiNₓ (x is a positive number)), etc. The first interlayer insulating film 65 preferably has a thickness of 600 nm or more and 1000 nm or less. This is because it may be disadvantageously difficult to planarize the first interlayer insulating film 65 if the thickness of the first interlayer insulating film 65 is less than 600 nm, and it may be disadvantageously difficult to form the contact hole 84 by etching if the thickness is more than 1000 nm

As shown in FIG. 22, the CF substrate 53 includes an insulating substrate 71, such as a glass substrate etc., a color filter 72 provided on the insulating substrate 71, a common electrode 74 covering the color filter 72 in the reflective region R, column-like photospacers (not shown) provided on the common electrode 74, and an alignment film 76 covering the common electrode 74 and the photospacers.

As shown in FIG. 22, the color filter 72 includes a plurality of color layers 78 (i.e., a a red layer R, a green layer G, and a blue layer B), one for each pixel, and a black matrix 83 which is a film for blocking light. The black matrix 83 is provided between adjacent color layers 78 to separate the color layers 78 from each other.

The black matrix 83 is made of a metal material (tantalum (Ta), chromium (Cr), molybdenum (Mo), nickel (Ni), titanium (Ti), copper (Cu), aluminum (Al), etc.), a resin material in which a black pigment (carbon particles etc.) is dispersed, or a resin material including a multilayer structure of a plurality of light-transmissive color layers having different colors, etc. The photospacer is made of an acrylic photosensitive resin and formed by photolithography, for example.

In this embodiment, the pixel electrode 69, the liquid crystal layer 54 formed on the pixel electrode 69, the common electrode 74 formed on the liquid crystal layer 54 constitute a liquid crystal display element 85.

In the reflective liquid crystal display device 70 thus configured, light entering from the CF substrate 53 is reflected by the reflective electrode 82 in the reflective region R.

The liquid crystal display device 70 includes pixels, one for each pixel electrode 69. In each pixel, when the TFT element 55 is turned on by a gate signal sent from the gate line 61, predetermined charge is written through the source electrode 68 and the drain electrode 77 to the pixel electrode 69 by a source signal sent from the source line 64. As a result, a potential difference occurs between the pixel electrode 69 and the common electrode 74, whereby a predetermined voltage is applied to the liquid crystal layer 54. In the liquid crystal display device 70, by utilizing the fact that the alignment of liquid crystal molecules varies depending on the magnitude of the applied voltage, the reflectance of light entering from the CF substrate 53 is adjusted to display an image.

Here, as in the first embodiment, as shown in FIGS. 21 and 22 the liquid crystal display device 70 of this embodiment includes the honeycomb-shaped structural element 30 on a surface 56b of the insulating substrate 56 opposite to the liquid crystal display element 85.

More specifically, the honeycomb-shaped structural element 30 for improving the stiffness of the liquid crystal display device 70 is provided on the surface 56b of the insulating substrate 56 opposite to a surface 56a on which the liquid crystal display element 85 is provided. As in the first embodiment, the honeycomb-shaped structural element 30 is provided on the surface 56b of the insulating substrate 56 with the adhesive layer 31 being interposed therebetween.

With this configuration, advantages similar to those of (1)-(4) can be obtained. Specifically, the stiffness of the liquid crystal display device 70 can be improved, whereby the bending due to the own weight can be reduced or prevented, and therefore, the occurrence of deformation, such as warp, swell, etc. can be reduced or prevented in the liquid crystal display device 70. As a result, the display performance of the liquid crystal display device 70 can be improved.

Because the bending due to the own weight can be reduced or prevented, even when the liquid crystal display device 70 is held by grasping an end portion thereof, the liquid crystal display device 70 sustains itself (i.e., does not bend or deform) against the support at the end portion. Therefore, the self-sustaining capability of the liquid crystal display device 70 can be improved.

Even if the liquid crystal display device 70 is bent by external force, such as mechanical stress etc., the cell wall 30a of the honeycomb-shaped structural element 30 can disperse stress 40, whereby the concentration of the stress at a predetermined portion of the liquid crystal display device 70 can be reduced or prevented. Therefore, the occurrence of damage (a crack etc.), disconnection due to a break in metal wiring, and destruction of the TFT element 55 can be reduced or prevented in the liquid crystal display device 70, and a decrease in the yield of the liquid crystal display device 70 can be reduced or prevented.

Also, even when the user intentionally applies stress to the liquid crystal display device 70, the liquid crystal display device 70 can be deformed into a desired shape without the occurrence of damage (a crack etc.), disconnection due to a break in metal wiring, and destruction of the TFT element 55.

According to this embodiment described above, advantages similar to those of (5)-(7) can be obtained.

Note that the embodiment described above may be changed.

In the embodiment, the honeycomb-shaped structural element 30 is provided in which the cell wall 30a is arranged in the shape of substantially a hexagon in cross-section, and the cells 30b separated from each other by the cell wall 30a each have the shape of substantially a hexagon in cross-section. Alternatively, the arrangement of the cell wall 30a and the cross-sectional shape of the cell 30b may be appropriately changed as long as the advantages of (1)-(4) are provided.

For example, as shown in FIG. 23, a structural element 43 may be used in which a cell wall 43a is arranged in the shape of substantially a circle in cross-section, and cells 43b separated from each other by the cell wall 43a each have the shape of substantially a circle in cross-section. Alternatively, for example, as shown in FIG. 24, a structural element 47 may be used in which a cell wall 47a is arranged in the shape of substantially a triangle in cross-section, and cells 47b separated from each other by the cell wall 47a each have the shape of substantially a triangle in cross-section.

Alternatively, as shown in FIG. 17, in the organic EL display device 1 of FIG. 2, the honeycomb-shaped structural element 30 may be covered by a coating layer 45. A resulting laminated structural element 46 including the honeycomb-shaped structural element 30 and the coating layer 45 may be provided or stacked on the surface 2b of the organic substrate 2 with the adhesive layer 31 being interposed therebetween. With this configuration, damage to the organic substrate 2 to which the honeycomb-shaped structural element 30 is attached can be effectively reduced or prevented.

Similarly, in the liquid crystal display device 70 of FIG. 22, the honeycomb-shaped structural element 30 may be covered by a coating layer 45. A resulting laminated structural element 46 including the honeycomb-shaped structural element 30 and the coating layer 45 may be provided or stacked on the surface 56b of the insulating substrate 56 with the adhesive layer 31 being interposed therebetween. With this configuration, damage to the insulating substrate 56 to which the honeycomb-shaped structural element 30 is attached can be effectively reduced or prevented.

The coating layer 45 may be made of, for example, epoxy resin. The coating layer 45 may be formed by, for example, coating the surface of the honeycomb-shaped structural element 30 with epoxy resin using CVD. Alternatively, the sheet-shaped coating layer 45 made of polyethylene terephthalate (PET) or polyethylene naphthalate (PEN) may be attached to the surface of the honeycomb-shaped structural element 30 to form the laminated structural element 46. The coating layer 45 may have a thickness of, for example, 300 μm.

Note that the structural element 41 of FIG. 14 and the structural elements 43 and 47 of FIGS. 23 and 24 may be covered by the coating layer 45, whereby similar advantages can be obtained.

In the liquid crystal display device 70 described in the third embodiment, the structural element 41 of the second embodiment may be used instead of the honeycomb-shaped structural element 30. In this case, the cell wall 42 of the structural element 41 includes the first cell wall 42a extending in the bending direction of the liquid crystal display device 70 and the second cell wall 42b extending in a direction perpendicular to the bending direction. With this configuration, an advantage similar to that of (8) can be obtained.

While, in the above embodiment, the TFT element 4 is made of amorphous silicon, the TFT element 4 may instead include, as a channel, a zinc oxide-based semiconductor, an organic semiconductor, or a carbon nanotube. With this configuration, similar to the TFT made of amorphous silicon, the TFT element 4 can be made of the widely used material, and therefore, the TFT element 4 can be used to provide a larger screen.

In this embodiment, an organic electro-luminescence (EL) display and a liquid crystal display (LCD) have been described as the display device. Alternatively, the display device may be an electrophoretic display, a plasma display (PD) display, a plasma addressed liquid crystal (PALC) display, an inorganic electro-luminescence (EL) display, a field emission display (FED), or a surface-conduction electron-emitter display (SED), etc.

### INDUSTRIAL APPLICABILITY

As described above, the present invention is useful for display devices having flexibility, such as an organic EL display device etc.

### DESCRIPTION OF REFERENCE CHARACTERS

1 ORGANIC EL DISPLAY DEVICE

2 ORGANIC SUBSTRATE

2b SURFACE OF ORGANIC SUBSTRATE

4 TFT ELEMENT

7 THE FIRST ELECTRODE

8 ORGANIC EL LAYER

10 SECOND ELECTRODE

11 ORGANIC EL DISPLAY ELEMENT

30 STRUCTURAL ELEMENT

30a CELL WALL

30b CELL

31 ADHESIVE LAYER

40 STRESS

41 STRUCTURAL ELEMENT

42 CELL WALL

42a FIRST CELL WALL

42b SECOND CELL WALL

43 STRUCTURAL ELEMENT

45 LAMINATED LAYER

47 STRUCTURAL ELEMENT

54 LIQUID CRYSTAL LAYER

56 INSULATING SUBSTRATE

56b SURFACE OF INSULATING SUBSTRATE

69 PIXEL ELECTRODE

70 LIQUID CRYSTAL DISPLAY DEVICE

74 COMMON ELECTRODE

85 LIQUID CRYSTAL DISPLAY ELEMENT

X THICKNESS DIRECTION OF STRUCTURAL ELEMENT

Y BENDING DIRECTION

Z DIRECTION PERPENDICULAR TO BENDING DIRECTION

1. A display device including a substrate and a display element provided on the substrate, wherein
a structural element including a plurality of cells separated from each other by a cell wall is provided on a surface opposite to the display element of the substrate.

2. The display device of claim 1, wherein
the cell wall is made of a resin material or a metal material.

3. The display device of claim 1, wherein
an adhesive layer is provided on the surface of the substrate, and the structural element is provided on the substrate with the adhesive layer being interposed therebetween.

4. The display device of claim 1, wherein
the structural element has a thickness of 10 micrometers to 1 millimeter.

5. The display device of claim 1, wherein
the structural element is covered by a coating layer.

6. The display device of claim 1, wherein
the cell wall includes a first cell wall extending in a bending direction of the display device and a second cell wall extending in a direction perpendicular to the bending direction.

7. The display device of claim 1, wherein
the display element is an organic EL display element.

8. The display device of claim 1, wherein
the display element is a liquid crystal display element.
